(19) United States
(12) Patent Application Publication
(10) Pub. No.: US 2009/0212316 A1
(43) Pub. Date: Aug. 27, 2009

(54) Surface-mounted optoelectronic semiconductor component and method for the production thereof

(75) Inventors: Bert Braune, Wenzenbach (DE); Herbert Brunner, Sinzing (DE); Thomas Höfer, Lappersdorf (DE); Harald Jäger, Regensburg (DE); Raimund Schwarz, Regensburg (DE)

Correspondence Address: COHEN, PONTANI, LIEBERMAN & PAVANE LLP, 551 FIFTH AVENUE, SUITE 1210, NEW YORK, NY, 10176, US

(73) Assignee: Osram Opto Semiconductors GmbH, Regensburg (DE)

(21) Appl. No.: 11/991,230

(22) PCT Filed: Aug. 24, 2006
(86) PCT No.: PCT/DE2006/001492

§ 371 Date: May 11, 2009

(30) Foreign Application Priority Data
Aug. 30, 2005 (DE) 102005041064.2

(51) Int. Cl. H01L 33/00; H01L 31/0203; H01L 21/56

(52) U.S. Cl. 257/99; 257/433; 438/113; 361/56; 257/98; 257/E33.059; 257/E31.117; 257/E21.502

(57) ABSTRACT

A surface-mounted component, comprising an optoelectronic semiconductor chip, a molded body integrally molded onto the semiconductor chip, a mounting area formed at least in places by a surface of the molded body, at least one connection location and side areas of the component which are produced by means of singulation.

The document U.S. Pat. No. 4,843,280 describes an optoelectronic component.

A surface-mounted optoelectronic component and a method for the production of such a component are specified.

One object is to specify a surface-mounted optoelectronic component in which the ratio of housing volume to chip volume is as small as possible.

In accordance with at least one embodiment of the surface-mounted component, the surface-mounted component has an optoelectronic semiconductor chip. The optoelectronic semiconductor chip can be a radiation-receiving or a radiation-emitting semiconductor chip. By way of example, the semiconductor chip is a luminescence diode chip such as, for instance, a light-emitting diode chip or a laser diode chip. Furthermore, it is possible for the optoelectronic semiconductor chip to be a photodiode chip. Furthermore, the optoelectronic component can comprise a plurality of such semiconductor chips. In this case, the optoelectronic component can in particular also comprise a radiation-receiving and a radiation-generating semiconductor chip. It is furthermore possible for the optoelectronic component to comprise luminescence diode chips suitable for generating electromagnetic radiation of mutually different wavelengths.

In accordance with at least one embodiment of the optoelectronic component, the optoelectronic component has a molded body. Preferably, the molded body is integrally molded onto the optoelectronic semiconductor chip at least in places. That is to say that the material of the molded body—the molding compound—is in contact with the semiconductor chip. Particularly preferably, the molded body encapsulates the semiconductor chip in a positively locking manner at least in places. In this case, the molded body is composed of a material which is transmissive at least to a part of the electromagnetic radiation which is emitted by the optoelectronic semiconductor chip during operation of the component or is intended to be received by it. Preferably, the molded body is a plastic molded body containing or comprising a plastic. The optoelectronic semiconductor chip is preferably encapsulated with the molding compound of the molded body by casting or injection molding. That is to say that the molded body is preferably produced by means of a casting or molding method. In this case, the molded body simultaneously constitutes a potting of the semiconductor chip and a housing for the component.

In accordance with at least one embodiment of the surface-mounted component, the component has a mounting area provided by a part of the surface of the molded body. In this case, the mounting area of the component denotes that area of the component which faces a carrier—for example a circuit board—onto which the surface-mounted component is mounted. In this case, the mounting area can be a supporting area with which the component bears on the carrier. For this purpose, the mounting area can be in mechanical contact with the carrier at least in places. It is furthermore possible for the mounting area to be in contact with a connection material—for example a solder via which electrical contact is made with the surface-mounted component. That is to say that the connection material then wets parts of the mounting area and thus parts of the molded body.

In accordance with at least one embodiment of the surface-mounted component, the surface-mounted component has at least one connection location.

In this case, the connection locations of the surface-mounted component are provided for making electrical contact with the component. They are preferably situated at least partly in the molded body.

Preferably, the connection locations are externally accessible at the mounting area of the surface-mounted component. That is to say that electrical contact can be made with the component at the mounting area of the surface-mounted component.

In accordance with at least one embodiment, the component furthermore has side areas produced by means of singulation. The side areas are those areas of the component which laterally enclose the mounting area and run for example in a direction transversely with respect to the mounting area.

The side walls are preferably produced by means of singulation. In particular, therefore, the contour and form of the side walls are not produced by a casting or molding process, but rather by means of a singulation process of the molded body. The singulation can be effected for example by means of sawing, cutting or producing a breaking edge and subsequent breaking. That is to say that a material removal preferably takes place during singulation to form individual components. The side areas of the molded body and thus the side areas of the component are then produced by means of a material removal. The side areas then preferably have traces of a material removal. If the production of the surface-mounted component involves singulation both through the molded body and through the connection locations, that is to say if sawing, cutting or breaking is effected for example through the connection locations as well, then the connection locations terminate at the side areas, that is to say laterally flush with the molded body.

In other words, preferably, the molded body protrudes laterally beyond the connection locations or the latter terminate laterally flush with the molded body. In this case, laterally denotes those directions which run in a plane extending parallel or substantially parallel to the mounting area. That is to say that the connection locations are situated at the mounting area of the component and do not project beyond the side areas of the surface-mounted component. The side areas can be formed in planar fashion, for example. In other words, the side areas are formed in a manner free of projections in this case. This is possible primarily because the side areas are produced by singulation and therefore the molded body protrudes beyond the connection locations or the latter terminate flush with said molded body and, as a result, the connection locations cannot pierce the side areas or project from them.

Preferably, both the connection locations and a part of the molded body are freely accessible at the mounting area of the surface-mounted component.

In accordance with at least one embodiment of the surface-mounted optoelectronic component, the component has an optoelectronic semiconductor chip, a molded body integrally molded onto the semiconductor chip, a mounting area formed at least in places by a surface of the molded body, at least one connection location, and side areas of the component which are produced by means of singulation.

In this case, the surface-mounted component makes use of the idea, inter alia, that a molded body serving as potting and housing for a surface-mounted optoelectronic chip enables a component having a particularly small form factor. That is to say that the ratio of housing volume to chip volume is particularly small in the case of this component. If, moreover, the electrical connection locations of the component are also arranged in such a way that they terminate laterally at most with the molded body and do not protrude beyond the latter in laterally flush fashion—that is to say if side areas of the component are produced by a singulation process—then this results in a particularly compact surface-mounted optoelectronic component. Such a component is particularly well suited for example to use as a luminescence diode or optical detector in particularly small devices such as mobile phones, photographic mobile phones or digital image cameras. Space for mounting optoelectronic components is available only to a very limited extent in these devices.

In accordance with at least one embodiment of the optoelectronic component, the molded body is integrally molded onto the connection locations of the component. That is to say that the molded body preferably encloses the connection locations of the component in a positively locking manner at least in places. In this case, the connection locations preferably each have an area via which electrical contact can be made with them from outside the component. That is to say that the connection location is then not enclosed by the molded body at least at the connection area.

In accordance with at least one embodiment of the optoelectronic component, at least one connection location of the component has an anchoring structure suitable for improving an adhesion of the molded body at the connection location. In this case, the anchoring structure can be provided for example by a roughening of the surface of the connection location. In this case, roughened regions of the surface of the connection location are in contact with the molded body. Roughening the surface of the connection location increases the contact area between connection location and molded body.

Furthermore, the anchoring structure can be provided by an undercut of the connection location. In this case, the connection location has an overhang that counteracts delamination of the molded body.

Particularly preferably, the anchoring structures can also be formed as barbs that engage into the molded body and retain and fix it at the connection locations.

In accordance with at least one embodiment of the surface-mounted component, at least one of the connection locations of the component has a mushroom-shaped structure. In this case, the cap of the connection location formed in mushroom-shaped fashion is preferably arranged on that side of the connection location which is remote from the mounting area of the component. Such a connection location formed in mushroom-shaped fashion can primarily inhibit or prevent the potting compound from being stripped away in a direction directed away from the mounting area. By way of example, such a mushroom-shaped connection location can be produced by undercut-etching or undercutting a metallic connection location.

In accordance with at least one embodiment of the surface-mounted component, at least one of the connection locations of the component has an etched structure. By way of example, the etched structure is an undercut. In this case, the etched structure is preferably situated within the molded body and is enclosed by the latter in a positively locking manner. On account of the undercut, the connection location preferably has an abruptly increasing diameter in a direction directed away from the mounting area. That part of the molded body which is integrally molded onto the connection location at the undercut therefore counteracts a stripping away of the molded body in a direction directed away from the mounting area.

In accordance with at least one embodiment of the surface-mounted component, at least one of the connection locations of the surface-mounted component has a mounting area onto which the optoelectronic semiconductor chip is fixed. In this case, the mounting area of the connection location is preferably formed by an area of the connection location which is remote from the mounting area of the optoelectronic semiconductor chip. The chip can for example be conductively connected to the mounting area of the connection location. For this purpose, the chip can be bonded, soldered or electrically conductively adhesively bonded onto the mounting area. A second electrical contact of the optoelectronic semiconductor chip is then provided by a wire contact connection, for example, wherein a wire can be connected to a further connection location of the component.

It is furthermore possible for the chip to be electrically non-conductively connected to the connection location onto which it is applied.

Electrical contact with the chip can then be realized by means of two wire contact connections, wherein wires are connected to two further connection locations of the component.

Furthermore, it is also possible for the optoelectronic semiconductor chip to be applied onto the mounting areas of two different connection locations using so-called flip-chip technology. A wire contact connection can be omitted in this embodiment.

In accordance with at least one embodiment of the surface-mounted component, at least one of the connection locations of the component has a mounting area onto which an ESD (electrostatic discharge) protection element is applied. This can involve that connection location onto which the chip, too, has already been applied. Preferably, however, the ESD protection element is applied onto a further connection location. The ESD protection element is suitable for conducting away voltage spikes that occur for example in the reverse direction of the optoelectronic semiconductor chip. The ESD protection element is for example one of the following components: varistor, light-emitting diode chip, zener diode, resistor. In this case, the ESD protection element is connected in parallel or in antiparallel with the optoelectronic semiconductor chip.

If the ESD protection element is a light-emitting diode chip, for instance, then the latter is connected in antiparallel with the optoelectronic semiconductor chip. Said light-emitting diode chip can then likewise be utilized for generating radiation.

In accordance with at least one embodiment of the surface-mounted component, at least one of the connection locations of the component has a connection area via which electrical contact can be made with the semiconductor chip. Preferably, electrical contact can be made with the connection area from outside the component. By way of example, the connection area is provided by that area of the connection location which faces the mounting area of the component. The connection area of the connection location is then for example remote from a mounting area of the connection location. Preferably, the connection location is freely accessible at the mounting area of the component and electrical contact can be made with it there.

Particularly preferably, each connection location of the component has such a connection area.

In accordance with at least one embodiment of the surface-mounted component, the connection area of at least one connection location of the component terminates flush with the mounting area of the component. That is to say that the connection location does not protrude beyond the mounting location. In other words, the mounting area in the region of the connection location is formed by the connection area of the connection location. Such an embodiment of the connection area results in a particularly compact surface-mounted component in which the outer form is determined only by the molded body, and no further component parts project from the latter.

In accordance with at least one embodiment of the surface-mounted component, the connection area of at least one connection location of the component projects beyond the mounting area of the component. That is to say that, in this embodiment of the component, the connection location protrudes at least a little beyond the mounting area of the component. Particularly preferably, the protrusion of the connection location is small relative to the total height of the surface-mounted component. In this case, the total height of the component is given by the distance from the connection area of the connection location to the surface of the component opposite the mounting area. In this embodiment of the surface-mounted component, the connection locations are particularly readily externally accessible and contact-connectable.

In accordance with at least one embodiment of the surface-mounted component, the connection area of at least one of the connection locations of the component is arranged in a cutout of the mounting area. That is to say that the mounting area has a hole, for example, via which the connection area is accessible. The connection area is situated completely in the molded body in this embodiment. A connection material—for example a solder—can be drawn for instance by capillary forces into the cutout of the mounting area and in this way makes contact with the surface-mounted component at the connection area.

It is furthermore possible for the connection area to be coated with a connection material in such a way that the connection material terminates flush with the mounting area of the component or protrudes slightly beyond said mounting area. This design of the surface-mounted component results in a particularly flat mounting of the component. The component can bear with its mounting area directly on a carrier—no or hardly any connection material being situated between carrier and mounting area.

In accordance with at least one embodiment of the surface-mounted component, at least one connection area of the component is coated at least in places with a material suitable for improving the adhesion to the molded body. In this case, preferably only regions of the connection locations which are in contact with the molded body are coated. In particular, the connection area of the connection location preferably remains free of the material. Particularly preferably, all the connection locations of the component are coated with the material.

In accordance with at least one embodiment of the surface-mounted component, the optoelectronic semiconductor chip is coated at least in places with the material suitable for improving the adhesion to the molded body.

In accordance with at least one embodiment of the surface-mounted component, the ESD protection element connected in parallel or in antiparallel with the optoelectronic semiconductor chip is coated at least in places with the material suitable for improving the adhesion to the molded body.

In accordance with at least one embodiment of the surface-mounted component, a contact-making wire provided for making electrical contact with the optoelectronic semiconductor chip is coated at least in places with the material suitable for improving the adhesion to the molded body.

Preferably, all the contact-making wires of the component are coated with the material in this way.

In accordance with at least one embodiment of the surface-mounted component, all the component parts of the component which are situated within the molded body are coated at least in places with the material suitable for improving an adhesion between the component parts of the component and the molded body.

In accordance with at least one embodiment of the surface-mounted component, the material suitable for improving the adhesion to the molded body contains a silicate. Preferably, the silicate layer is applied before the component is potted with the molded body or encapsulated with the molded body by injection molding. By way of example, the silicate layer is applied by means of flame pyrolysis. In this way it is possible to apply a layer having a thickness of at most 40 nanometers, preferably at most 20 nanometers, particularly preferably at most 5 nanometers. A silicate coating applied in this way is then an extremely thin, very dense retaining layer that has a high surface energy and is therefore suitable for improving the adhesion of the molded body to the component parts of the component such as connection locations, chip, ESD protection element and contact-making wires.

At least in one embodiment of the surface-mounted component, the molded body contains a silicone.

Preferably, the molded body contains or comprises a reaction-curing silicone molding compound.

In accordance with at least one embodiment of the surface-mounted component, the molded body contains or comprises an epoxy resin.

In accordance with at least one embodiment of the surface-mounted component, the molded body contains or consists of an epoxide-silicone hybrid material. In the case of molding compounds which also contain a silicone alongside an epoxy resin, the aging stability of the molded body is improved. The molded body is then for example particularly stable against ultraviolet radiation. Furthermore, the molding compound can be adapted to the requirements of the component and of the production process for example by means of the mixing ratio of silicone and epoxy resin. Thus, epoxide-silicone hybrid materials generally cure faster than pure silicone molding compounds and are distinguished by an improved mechanical stability. A molded body composed of this material can therefore be removed more easily from a casting molding die or compression molding die. Moreover, shorter process times are possible, which enables a more cost-effective production of the component. In this case, by way of example, a molding compound containing approximately 50 percent silicone and approximately 50 percent epoxy resin proves to be particularly advantageous.

In this case, the surface-mounted component described here makes use of the insight, inter alia, that a mechanically particularly stable component is achieved by means of suitable embodiment of the connection locations—for example by means of connection locations with anchoring structures or mushroom-shaped connection locations, a coating of the component parts with a material that improves the adhesion between molded body and component parts of the component, and a molding compound containing a silicone. The combination of the measures described produces a component having a very low tendency toward delamination, high mechanical stability and improved aging properties. Moreover, a very compact design is realized by virtue of the arrangement of the connection locations of the component at the mounting area.

In accordance with at least one embodiment of the surface-mounted component, the molded body contains diffuser particles. The diffuser particles are particles suitable for scattering electromagnetic radiation that is to be emitted or received by the optoelectronic semiconductor chip.

In accordance with at least one embodiment of the surface-mounted component, the molded body contains radiation-absorbing particles suitable for absorbing electromagnetic radiation of a specific wavelength range. Such particles can be used as a filter in the component. If the optoelectronic semiconductor chip is a detector, for example, a detector having a particularly high sensitivity in a specific wavelength range is realized in this way.

In accordance with at least one embodiment of the surface-mounted component, the molded body contains glass fibers. The glass fibers can further improve the mechanical stability of the molded body, by way of example.

In accordance with at least one embodiment of the surface-mounted component, the molded body contains a mold release agent. The mold release agent can prove to be particularly advantageous during the production of the component since the detachment of the molded body from the casting molding die or compression molding die is facilitated using the mold release agent.

In accordance with at least one embodiment, the molded body contains a luminescence conversion material. The luminescence conversion material is preferably suitable for absorbing at least part of an electromagnetic radiation of a first wavelength range that is emitted by the optoelectronic semiconductor chip during operation and/or is to be received by the semiconductor chip and for emitting electromagnetic radiation originating from a second wavelength range, which is different from the first wavelength range. In particular inorganic phosphor powders can be mixed into silicone-containing molding compounds in a particularly simple manner. Cesium-doped yttrium aluminum garnet and cesium-doped terbium aluminum garnet powders shall be mentioned in this regard by way of example. Suitable organic and inorganic phosphors are mentioned for example in the documents WO 01/50540A1 and WO 98/12757A1, the disclosure content of which relating to the phosphors is hereby incorporated by reference.

In accordance with at least one embodiment of the surface-mounted component, the molded body has a further inner layer. The inner layer of the molded body is integrally molded onto the optoelectronic semiconductor chip. That is to say that the inner layer encloses the optoelectronic semiconductor chip.

Furthermore, the molded body has an outer layer, which lies remote from the semiconductor chip and is bounded for example by that surface of the molded body which is remote from the mounting area. A layer containing a luminescence conversion material is then situated between the outer layer and the inner layer. That is to say that the phosphor particles of the luminescence conversion material are arranged in a layer above the optoelectronic semiconductor chip. In this case, the inner layer and the outer layer are preferably free of a luminescence conversion material. However, said layers can contain other materials such as, for example, light-scattering particles.

In accordance with at least one embodiment of the surface-mounted component, the molded body of the component has a radiation passage area formed in lenslike fashion. In this case, the radiation passage area is formed for example by that surface of the molded body which is remote from the mounting area. In this case, formed in lenslike fashion can mean that the radiation passage area has a curvature. By way of example, the radiation passage area can be curved convexly outwardly. The radiation passage area can then be curved in the manner of a spherical, elliptical or aspherical lens. The curvature of the radiation passage area can be used, on the one hand, for the beam shaping of electromagnetic radiation that emerges from the component or enters into the component. On the other hand, it is possible for the probability of light emerging from the molded body to be increased on account of the curvature of the radiation passage area. This is due to the fact that, by way of example, a spherical curvature of the radiation passage area reduces the probability of total reflection of electromagnetic radiation upon emergence from the molded body.

Furthermore, a method for the production of a surface-mounted optoelectronic component is specified. By way of example, a component according to one of the embodiments above can be produced by means of the method.

In accordance with at least one embodiment of the method, firstly a multiplicity of optoelectronic semiconductor chips area arranged in the cavity of a compression molding die or casting molding die. In this case, the optoelectronic semiconductor chips have for example already been applied to connection locations and electrically contact-connected by means of connection wires, for example. The connection locations can be applied for example on a common substrate. It is furthermore possible for the connection locations to be part of a leadframe or film.

The semiconductor chips are subsequently encapsulated with a common molded body. That is to say that the optoelectronic semiconductor chips together with the other component parts of the component are jointly potted or encapsulated by injection molding in the cavity. This gives rise to a block with a multiplicity of optoelectronic semiconductor chips surrounded by a common molding compound. After the curing of the molding compound, the molding compound forms a molded body integrally molded onto the optoelectronic semiconductor chips.

In a subsequent method step, the common molded body is then severed for singulating the components. In this case, it is not absolutely necessary to produce components having in each case only a single optoelectronic semiconductor chip. It is also possible, for example, to combine a plurality of optoelectronic semiconductor chips in an individual component. This can in particular also involve different optoelectronic semiconductor chips such as, for example, luminescence diodes having different emission wavelengths or luminescence diode chips and photodiode chips.

In accordance with at least one embodiment of the method for the production of a surface-mounted component, exclusively the molded body is severed for singulating the component. That is to say that for singulating the component singulation is not effected through the connection locations of the component. In this case, the connection locations are surrounded by the molded body on all sides and are accessible only at their connection areas at the mounting area of the component. The molded body then protrudes beyond the connection locations in a lateral direction.

In accordance with at least one embodiment of the method for the production of a surface-mounted component, at least one connection location of the component is severed during the singulation of the components. That is to say that singulation is effected not only through the molded body but also at least one connection location of the component. This results in a component in which the molded body terminates laterally flush with a connection location.

In accordance with at least one embodiment of the method for the production of a surface-mounted component, the singulation is effected by means of sawing or cutting.

In accordance with at least one embodiment of the method for the production of a surface-mounted component, the connection locations are formed by a leadframe. The leadframe can be formed for example from a material having good electrical conductivity, such as copper. If the connection locations are formed as part of a leadframe, then singulation is preferably effected through the connection locations. The leadframe preferably has cutouts between the connection locations, said cutouts being filled with the molding compound during the process of encapsulation by injection molding or potting.

In accordance with at least one embodiment of the method for the production of a surface-mounted component, the connection locations are provided by the part of a plastic film having an electrically conductive coating for example composed of copper. That is to say that the individual connection locations are connected to one another by a plastic film which, after the process of encapsulation by injection molding or potting with the molding compound, is either removed or situated within the molded body. During the singulation of the components, singulation is then effected, if appropriate, both through the connection locations and through the plastic film.

In accordance with at least one embodiment, the molding compound that forms the molded body after curing contains at least one of the following materials: epoxide, silicone, epoxide-silicone hybrid material. Preferably, said materials are reaction-curing in this case. The molding compound can be present in liquid or pasty form in this case prior to the process of encapsulation by casting or injection molding.

Particularly preferably, the molding compound is a prereacted material present in solid form prior to further processing. This proves to be particularly advantageous for the further processing in particular also for epoxide-silicone hybrid materials.

In this case, the method described here makes use of the following insight, inter alia. In particular molding compounds containing a silicone have a particularly low viscosity during processing in a casting molding die or compression molding die. When potting components in individual cavities, said low viscosity leads to increased flash formation. Thickness fluctuations and fluctuations in the surface roughness for example of a substrate on which the connection locations are situated can be compensated for only with difficulty in the course of encapsulation in individual cavities. It has been shown, however, that these difficulties can be avoided when using silicone-containing molding compounds by means of a plurality of optoelectronic components being encapsulated by casting in a single cavity.

In accordance with at least one embodiment of the method described here, the component parts of the component are coated prior to encapsulation with the molding compound with a material suitable for increasing the adhesion to the molded body. The material is preferably a silicate. In this case, the material can be applied to the component parts of the component by means of flame pyrolysis. This gives rise to a layer of silicate having a thickness of at most 40 nanometers, preferably at most 20 nanometers, particularly preferably at most 5 nanometers, which layer encapsulates at least parts of the component parts of the component and imparts a particularly good adhesion to the molding compound.

The light-emitting diode arrangement described here is explained in more detail below on the basis of exemplary embodiments and the associated figures.

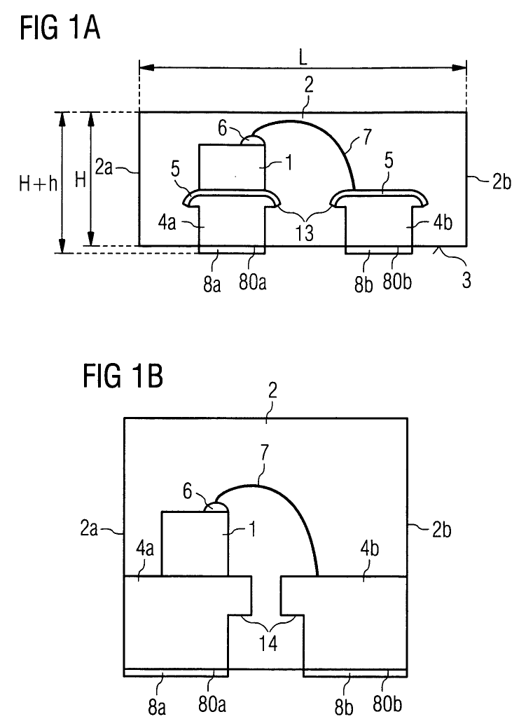

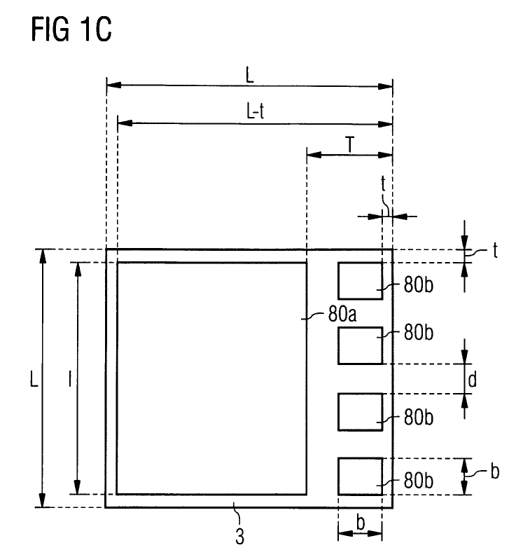

FIG. 1A shows a schematic sectional illustration of a first exemplary embodiment of the surface-mounted component described here.

FIG. 1B shows a schematic sectional illustration of a second exemplary embodiment of the surface-mounted component described here.

FIG. 1C shows a schematic plan view of the mounting area of a third exemplary embodiment of the surface-mounted component described here.

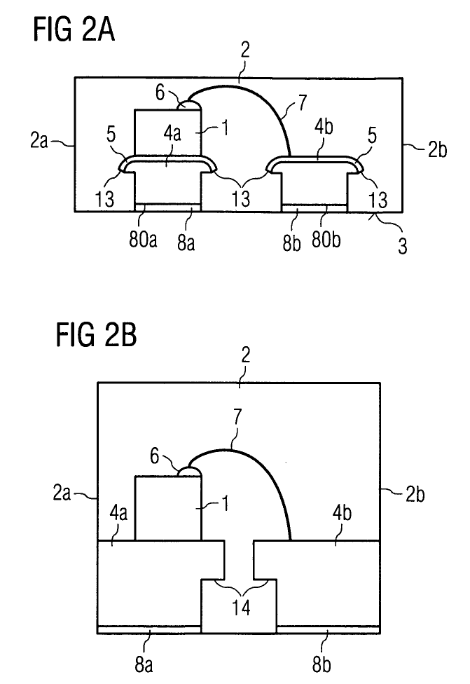

FIG. 2A shows a schematic sectional illustration of a fourth exemplary embodiment of the surface-mounted component described here.

FIG. 2B shows a schematic sectional illustration of a fifth exemplary embodiment of the surface-mounted component described here.

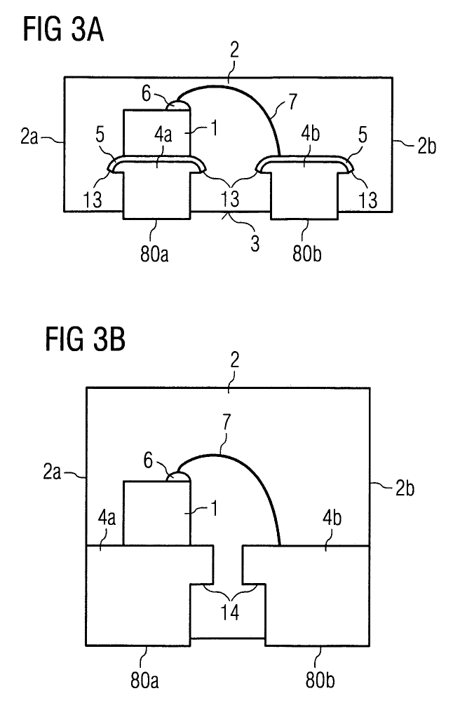

FIG. 3A shows a schematic sectional illustration of a sixth exemplary embodiment of the surface-mounted component described here.

FIG. 3B shows a schematic sectional illustration of a seventh exemplary embodiment of the surface-mounted component described here.

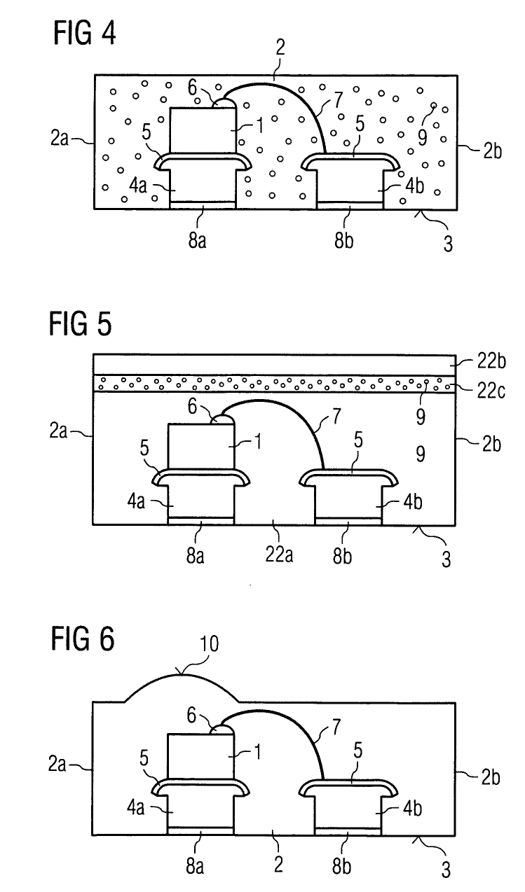

FIG. 4 shows a schematic sectional illustration of an eighth exemplary embodiment of the surface-mounted component described here.

FIG. 5 shows a schematic sectional illustration of a ninth exemplary embodiment of the surface-mounted component described here.

FIG. 6 shows a schematic sectional illustration of a tenth exemplary embodiment of the surface-mounted component described here.

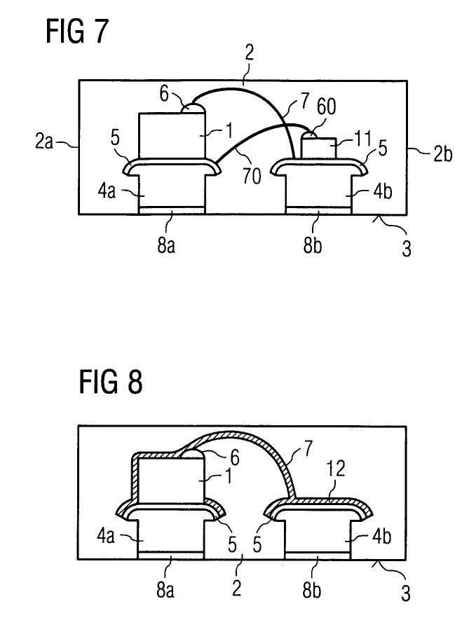

FIG. 7 shows a schematic sectional illustration of an eleventh exemplary embodiment of the surface-mounted component described here.

FIG. 8 shows a schematic sectional illustration of a twelfth exemplary embodiment of the surface-mounted component described here.

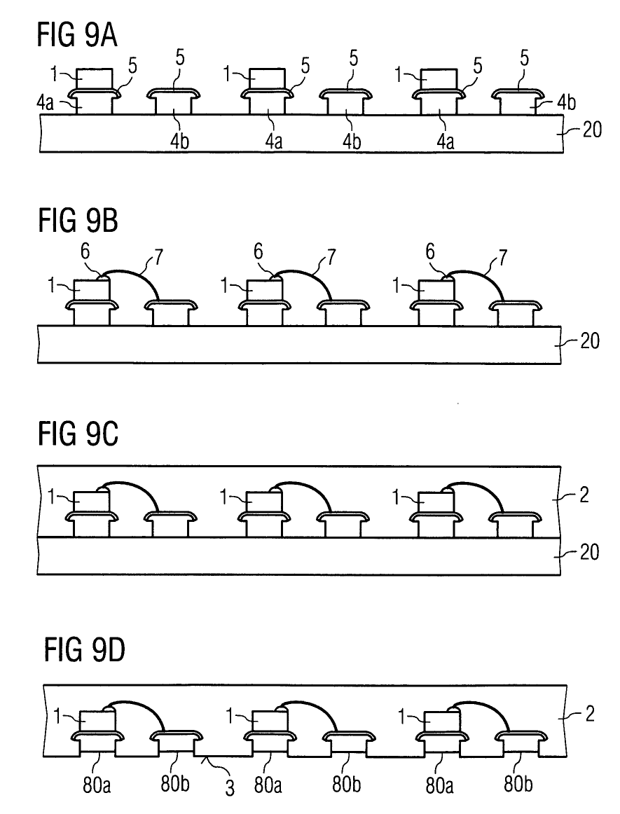

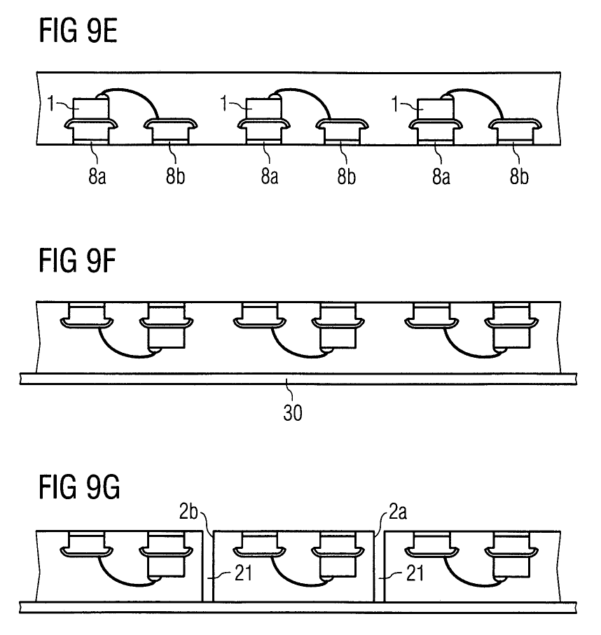

FIGS. 9A, 9B, 9C, 9D, 9E, 9F and 9G show schematic sectional illustrations for elucidating a first exemplary embodiment of the method described here.

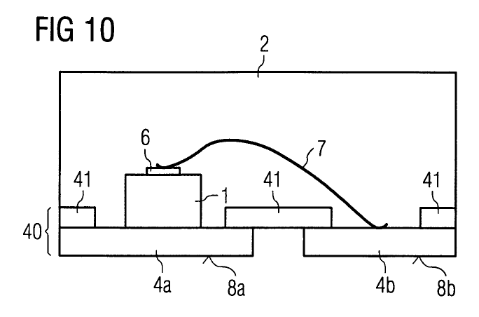

FIG. 10 shows a schematic sectional illustration of a surface-mounted component produced by means of a second exemplary embodiment of the method.

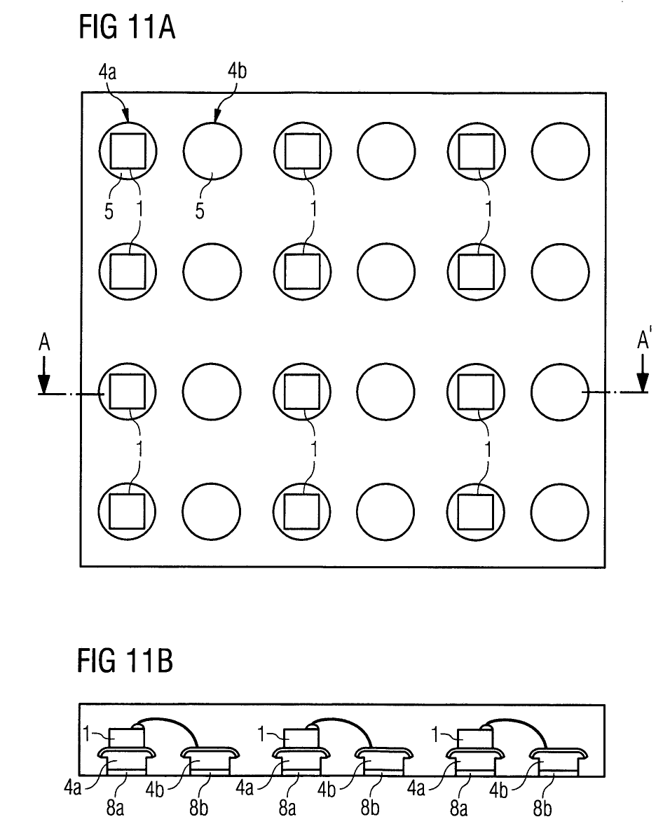

FIG. 11A shows a schematic plan view of a thirteenth exemplary embodiment of the surface-mounted component described here.

FIG. 11B shows a schematic sectional illustration along the line A-A′ of the surface-mounted component described in conjunction with FIG. 11A.

In the exemplary embodiments and figures, identical or identically acting constituent parts are in each case provided with the same reference symbols. The elements illustrated should not be regarded as true to scale, rather individual elements may be illustrated with an exaggerated size in order to afford a better understanding.

FIG. 1a shows a schematic sectional illustration of a first exemplary embodiment of the surface-mounted component described here.

The surface-mounted optoelectronic component has an optoelectronic semiconductor chip 1. The optoelectronic semiconductor chip 1 is for example a luminescence diode chip—for instance a laser diode chip or a light-emitting diode chip. However, the optoelectronic semiconductor chip 1 can also be a detector chip such as a photodiode, for example. By way of example, the semiconductor chip 1 is an Si photodiode chip.

Preferably, the optoelectronic chip 1 is an optoelectronic semiconductor component produced using thin-film technology. That is to say that, in at least one exemplary embodiment, the semiconductor chip 1 has a radiation coupling-out area through which a large part of the electromagnetic radiation emitted by the semiconductor chip 1 is coupled out. Particularly preferably, the entire radiation emitted by the semiconductor chip 1 emerges through the radiation coupling-out area. The radiation coupling-out area is provided for example by a part of the surface of the semiconductor chip 1. Preferably, the radiation coupling-out area is provided by a main area of the semiconductor chip 1 which is arranged for example parallel to an epitaxial layer sequence of the semiconductor chip 1 which is suitable for generating electromagnetic radiation.

For this purpose, the epitaxial layer sequence can have for example a pn junction, a double heterostructure, a single quantum well or particularly preferably a multiple quantum well structure (MQW). In the context of the disclosure, the designation quantum well structure encompasses in particular any structure in which charge carriers experience a quantization of their energy states as a result of confinement. In particular, the designation quantum well structure does not comprise any indication about the dimensionality of the quantization. Consequently, it encompasses, inter alia, quantum wells, quantum wires and quantum dots and any combination of these structures.

Preferably, the semiconductor chip 1 is a semiconductor chip in which the growth substrate is at least partly removed and to whose surface remote from the original growth substrate a carrier element is applied.

The carrier element can be chosen relatively freely, compared with a growth substrate. Preferably, a carrier element is chosen which, with regard to its coefficient of thermal expansion, is adapted particularly well to the radiation-generating epitaxial layer sequence.

Furthermore, the carrier element can contain a material having particularly good thermal conductivity. In this way, the heat generated by the semiconductor chip 1 during operation is dissipated particularly efficiently to the connection location 4a.

Such semiconductor chips 1 produced by removing the growth substrate are often referred to as thin-film semiconductor chips and are preferably distinguished by the following features:
a reflective layer or layer sequence is applied or formed at a first main area—facing toward the carrier element—of the radiation-generating epitaxial layer sequence and reflects at least part of the electromagnetic radiation generated in the epitaxial layer sequence back into the latter.
The epitaxial layer sequence preferably has a thickness of at most 20 μm, particularly preferably of at most 10 μm.
Furthermore, the epitaxial layer sequence preferably contains at least one semiconductor layer having at least one area having an intermixing structure. Said intermixing structure ideally leads to an approximately ergodic distribution of the light in the epitaxial layer sequence, that is to say that it has an as far as possible ergodically stochastic scattering behavior.

A basic principle of a thin-film semiconductor chip is described for example in the document I. Schnitzer et al., Appl. Phys. Lett. 63(16), 18 Oct. 1993, pages 2174 to 2176, the disclosure content of which relating to the basic principle of a thin-film semiconductor chip is hereby incorporated by reference.

In this case, such an optoelectronic semiconductor chip produced in thin-film chip has the advantage, inter alia, that, owing to its small height, it enables a surface-mounted component having a particularly small structural height.

The optoelectronic semiconductor chip 1 of the exemplary embodiment of FIG. 1 is applied to a connection location 4a of the component and electrically contact-connected to said connection location. By way of example, the optoelectronic semiconductor chip 1 is soldered, conductively adhesively bonded, or bonded onto the connection location 4a. For this purpose, the connection location 4a can have a coating 5 that improves the contact-connectability of the semiconductor chip at the connection location 4a. The coating 5 can contain gold, for example.

The connection locations 4a, 4b of the surface-mounted component contain copper, for example, or consist of copper. They are preferably produced by a sequence of etching steps and electrolytic coating steps. The connection locations 4a, 4b including coating 5 preferably have a height of 30 to 60 μm.

The connection locations 4a, 4b of the exemplary embodiment of FIG. 1 are formed in mushroom-shaped fashion. They have an anchoring structure 13 formed as a projection or overhang. In this case, the length of the projection in a lateral direction, that is to say in a direction parallel to the mounting area 3 of the component, is at least 3 μm. The height of the connection locations 4a and 4b up to the overhang is at least 20 μm. The distance between the two connection locations 4a and 4b of the exemplary embodiment of the surface-mounted component that is described in conjunction with FIG. 1 is preferably at least 140 μm.

In the exemplary embodiment of FIG. 1, the optoelectronic semiconductor chip 1 is electrically conductively connected to the second connection location 4b of the component by means of a contact-making wire 7. The contact-making wire 7 is provided by a gold wire, for example. The second connection location 4b can likewise have a coating 5 in order to improve the contact-connectability of the contact-making wire 7. The contact-making wire 7 is contact-connected for example by means of a bonding pad 6 on the top side of the optoelectronic semiconductor chip 1.

A molded body 2 is integrally molded onto the component parts of the component such as the optoelectronic semiconductor chip 1, the connection locations 4a, 4b, and the contact-making wire 7, at least in places. The molded body 2 preferably contains at least one of the following materials: epoxy resin, silicone, epoxide-silicone hybrid material. The molded body 2 preferably contains an epoxide-silicone hybrid material having a proportion of approximately 50 percent silicone and approximately 50 percent epoxide. It can be a reaction-curing material which has been prereacted prior to molding onto the component parts of the component. The molded body 2 is at least partly transmissive to electromagnetic radiation that is to be emitted or received by the optoelectronic semiconductor chip 1. That is to say that the molded body 2 is transparent or translucent to electromagnetic radiation at least in a specific wavelength range.

The side areas 2a, 2b of the component are produced by means of singulation after the curing of the molded body 2. That is to say that they are produced for example by means of sawing, cutting or breaking, wherein breaking involves firstly producing a desired breaking edge. The side areas 2a, 2b can therefore have traces of a material removal. The side areas 2a, 2b of the component are therefore formed in substantially planar or smooth fashion. In particular, the side areas 2a, 2b are free of macroscopic projections. That is to say that for example no connection locations of the component project from the side areas 2a, 2b. The molded body therefore protrudes beyond the connection locations 4a, 4b in a lateral direction, that is to say in a direction parallel to the mounting area 3 and transversely with respect to the side areas 2a, 2b.

The underside of the molded body forms at least one part of the mounting area 3 of the component. In the surface-mounted component, the mounting area 3 faces a component carrier (not shown) and can be in contact with such a component carrier at least in places.

A respective solder layer 8a, 8b is applied to the connection areas 80a, 80b of the connection locations 4a, 4b that face the mounting area 3. The solder layers 8a, 8b are provided by a nickel-gold layer sequence, for example. The component can then be mountable by means of a reflow soldering process, for example.

The length L of the component of the exemplary embodiment of FIG. 1 is preferably between 1.5 and 2.1 millimeters, particularly preferably approximately 1.8 millimeters. The total height H plus h of the component is between 0.5 and 0.9 millimeter, preferably 0.7 millimeter. In this case, the height H of the molded body is at least 0.3 millimeter.

FIG. 1b shows a schematic sectional illustration of a further exemplary embodiment of the surface-mounted optoelectronic component described here.

In a departure from the exemplary embodiment of FIG. 1, the connection locations 4a, 4b in this exemplary embodiment are provided by parts of a leadframe. In this case, the leadframe is structured by means of at least one etching process and has overhangs 14 serving for anchoring the connection locations 4a, 4b in the molded body 2. Likewise in contrast to the exemplary embodiment of FIG. 1a, the side areas 2a, 2b of the component in this exemplary embodiment are formed in places by the connection locations 4a, 4b. That is to say that, in the exemplary embodiment of the component described in conjunction with FIG. 1b, the molded body 2 terminates laterally flush with the connection locations 4a, 4b. In this case, laterally denotes that direction which runs transversely with respect to the side areas 2a, 2b of the component. That is to say that the connection locations 4a, 4b do not protrude laterally beyond the mounting area 3. The connection locations 4a, 4b do not project beyond the side areas 2a, 2b of the component, but rather terminate flush with said side areas.

FIG. 1c shows a plan view of the mounting area 3 of a third exemplary embodiment of one of the optoelectronic components described here. By way of example, this may involve the underside of a component in accordance with or similar to FIG. 1a or 1b.

The connection areas 80a, 80b of the connection locations 4a, 4b are freely accessible on the underside of the surface-mounted component at the mounting area 3, which is formed by a surface of the molded body 2. By way of example, said connection locations are provided with a coating 8a, 8b described above.

In this case, the connection locations 4b can be provided by a plurality of connection locations—there are four connection locations 4b in the exemplary embodiment of FIG. 1c. The connection locations 4a and 4b of the component are then dimensioned differently. That is to say that the component has differently dimensioned connection locations 4a, 4b. However, it is also possible for there to be just a single second connection location 4b, the connection area 80b of which can have for example the same dimensions as the connection area 80b of the first connection location 4a.

In the exemplary embodiment of FIG. 1C, the length of the connection locations 4a is l=1.7+/−0.035 millimeters. The length L of the component is 1.8+/−0.05 millimeters. The width of the connection area 80a is l−T=1.15+/−0.05 millimeters. The distance between the connection areas 80a, 80b and the side areas 2a, 2b of the component is t=0.05+/−0.03 millimeter. The distance between the connection areas 80b is D=0.2+/−0.05 millimeter. The width of the connection areas 80b is b=0.275+/−0.05 millimeter.

FIGS. 2a and 2b show schematic sectional illustrations of a fourth and a fifth exemplary embodiment of the surface-mounted component described here. In these exemplary embodiments, the coatings 8a, 8b of the connection areas 80a, 80b of the component terminate flush with the mounting area 3. The connection areas 80a, 80b of the connection locations 4a, 4b are therefore arranged in a cutout of the mounting area 3.

FIGS. 3a and 3b show schematic sectional illustrations of a sixth and a seventh exemplary embodiment of the surface-mounted component described here. In this exemplary embodiment, the connection locations 4a, 4b project slightly beyond the mounting area 3. The connection areas 80a, 80b of the connection locations 4a, 4b are arranged outside the molded body 2. The protrusion of the connection areas 4a, 4b is small here in relation to the height of the molded body 2.

FIG. 4 shows an eighth exemplary embodiment of the surface-mounted optoelectronic component described here. In supplementation for example to the exemplary embodiment of the component described in connection with FIG. 2a, here a further material 9 is present in the molded body 2. The further material 9 is for example particles suitable for scattering electromagnetic radiation—diffuser particles—, for absorbing electromagnetic radiation—absorbers—or for converting wavelengths—phosphors. Furthermore, it is possible for the molded body 2 to contain at least two of these particle types. That is to say that the molded body 2 can have for example diffuser particles and phosphor particles.

If the material 9 is for example phosphor particles of a luminescence conversion material, then the optoelectronic component can be suitable for emitting white light.

FIG. 5 shows a ninth exemplary embodiment of the optoelectronic component described here. In the exemplary embodiment of FIG. 5, the additional material 9 is arranged in a layer 22c. By way of example, the layer 22c is a layer of the molded body 2 which contains phosphor particles. The component in accordance with the exemplary embodiment of FIG. 5 additionally has a layer 22a of the molded body, which layer is free of the further material 9 and encloses the semiconductor chip 2. Furthermore, the component has a layer 22b, which likewise does not contain any further material 9. The layer 22b is bounded by the surface of the component which is remote from the mounting area 3 of the component.

FIG. 6 shows a tenth exemplary embodiment of the surface-mounted optoelectronic component described here. In this exemplary embodiment, the radiation passage area 10 of the component is formed in lenslike fashion. For this purpose, the radiation passage area can be curved at least in places in the manner of a spherical, elliptical or aspherical lens. Furthermore, it is possible for the radiation passage area to be formed at least in places in the manner of a Fresnel lens, a zone optic or a holographic optic. In this case, the structuring of the radiation passage area 10 can be provided, on the one hand, for the beam shaping of radiation that enters into the component or emerges from the component. On the other hand, it is possible for the configuration of the radiation passage area to reduce the probability of total reflection at the radiation passage area 10. In this way, more light can be coupled into or out of the component.

FIG. 7 shows an eleventh exemplary embodiment of the surface-mounted component described here. In the exemplary embodiment of FIG. 7, an ESD protection element is connected in parallel with the semiconductor chip 1. By way of example, a light-emitting diode 11 as ESD protection element is connected in antiparallel with the semiconductor chip 1. For this purpose, the light-emitting diode 11 is applied on the mounting area of the second connection location 4b and connected to the first connection location 4a by a contact-making wire 70. The contact-making wire 70 can be contact-connected to the light-emitting diode 11 for example by means of a bonding pad 60. The light-emitting diode 11 can also serve for generating radiation alongside a property as ESD protection element for the optoelectronic semiconductor chip 1. For this purpose, for example current of alternating direction can be applied to the connection locations 4a, 4b by means of a pulse width modulation circuit. This proves to be particularly advantageous, for example, if the semiconductor chip 1 itself is a light-emitting diode and the molded body 2 contains a luminescence conversion material. The component is then suitable for example by mixing the blue light of the optoelectronic semiconductor chip 1 and the wavelength-converted portion of the radiation—for example yellow light—for generating white light. The light-emitting diode 11 may then be suitable for generating light which increases the color rendering index of the light emitted by the component. By way of example, red light is involved in this case.

As an alternative to a light-emitting diode 11, the ESD protection element can also be provided by one of the following components: varistor, resistor, zener diode.

A twelfth exemplary embodiment of the surface-mounted component specified here is specified in conjunction with FIG. 8. In this exemplary embodiment, a coating 12 is applied at least in places to the component parts of the component, said coating containing a material that improves the adhesion of the component parts such as connection locations 4a, 4b, optoelectronic semiconductor chip 1, contact-making wire 7, to the molded body 2. That is to say that said coating 12 serves for avoiding a delamination of the molded body 2 from the component parts of the component.

The coating 12 preferably contains a silicate. It can be applied to at least individual component parts of the component for example by means of flame pyrolysis. The layer thickness of the coating 12 is at most 40 nanometers, preferably at most 20 nanometers, particularly preferably at most 5 nanometers. The coating 12 is distinguished by a strong adhesiveness to the component parts of the component and a high surface energy. The layer 12 is thereby suitable for imparting an adhesion between the component parts and the molded body 2, which preferably completely wets the layer 12.

By way of example, the silicate can be a stoichiometric silicate or a non-stoichiometric silicate (SiₓO_{y}). Furthermore, the silicate can comprise organic side groups, at least one organic side group, such as, for example one of the following side groups: vinyl, epoxy, amino.

Furthermore, as an alternative to the silicate types mentioned, other materials are also conceivable as adhesion promoters. Oxidic layers of other semiconductors or metals are appropriate, by way of example.

It should be pointed out here that, in particular, combinations of the configurations of the exemplary embodiments of FIGS. 4 to 8 are also possible. In particular, these configurations can find application in the exemplary embodiments of FIGS. 1 to 3.

An exemplary embodiment of the method described here is specified in conjunction with FIGS. 9A to 9G. The production method is suitable for producing an exemplary embodiment of the component as described in conjunction with FIG. 2A. In principle, however, the method can be used for producing all the exemplary embodiments of the component which are described here. The method is explained by means of schematic sectional illustrations in FIGS. 9A to 9G.

As shown in FIG. 9A, firstly a substrate 20 with a multiplicity of connection locations 4a, 4b is made available. In this case, the connection locations 4A, 4B are arranged in a two-dimensional array, only one row or line of which is shown in the sectional illustrations of FIGS. 9A to 9G. The substrate 20 for example comprises copper or consists of copper. It is preferably at least 120 μm thick.

The connection locations 4A, 4B are firstly provided with a coating 5 containing gold, for example. The coating 5 improves the contact-connectability of the optoelectronic semiconductor chip 1 and of the contact-making wire 7 at the connection locations 4a, 4b. An optoelectronic semiconductor chip 1 is subsequently bonded, conductively adhesively bonded, or soldered, onto the connection location 4a. The optoelectronic semiconductor chips 1 are bonded for example by their p sides onto the connection locations 4a.

Afterward (FIG. 9B), the optoelectronic semiconductor chips 1 are electrically conductively connected to the connection locations 4a for example on the n side by means of a bonding pad 9 to a contact-making wire 7.

Subsequently, by way of example, a silicate coating 12 (not illustrated for reasons of clarity) can be applied to the component parts of the component. The silicate coating 12 can be applied to the component parts for example by means of flame pyrolysis.

Afterward, the component parts of the component are introduced into the cavity of a casting molding die or compression molding die in order to produce a molded body 2. A molding compound is then filled into the cavity of the mold by means of transfer molding or injection molding. The molding compound is an epoxide- or silicone-containing molding compound. The molding compound is preferably an epoxide-silicone hybrid material. Silicones or hybrid materials containing silicones have a relatively low viscosity. During processing in individual cavities, this increases the flash tendency of the materials primarily in conjunction with leadframe-based components since sealing between leadframe or substrate 20 and the metal surface of the mold is difficult. In this case, a multiplicity of closing areas are present and the thickness fluctuations and fluctuations in the surface roughnesses within the substrate 20 can scarcely be compensated for in a mold. Furthermore, experience shows that silicones or hybrid materials containing a silicone are more brittle than epoxy-resin-based molding compounds. This results in a very small process window during deflashing methods such as, for example, during electrolytic deflashing or water jet deflashing. A potting of a multiplicity of components in a common cavity therefore proves to be particularly advantageous in the case of these materials.

Furthermore, a film molding process can be used during transfer molding of the molded body 2. In this case, the cavity of the mold is lined with a film having low adhesion to the molding compound used. A mold release agent can be dispensed with in this case. This increases the adhesion of the molded body to the component parts of the component.

In the subsequent method step, as shown in FIG. 9D, the substrate 20 of the connection locations 4a, 4b is removed. This can be done by means of an etching process, for example.

In a further method step shown in conjunction with FIG. 9E, a solder layer 8a, 8b is applied to the connection areas 80a, 80b of the connection locations 4a, 4b, which solder layer terminates flush with the mounting area 3 of the component or protrudes beyond said mounting area.

FIG. 9F shows the array of components laminated onto a film for further processing.

FIG. 9G shows the singulation of the components, which can be effected for example by means of sawing, cutting, laser cutting, water jet cutting or breaking.

As an alternative to connection areas 4a, 4b on a copper substrate 20, joint potting can also be effected on a film 40 comprising a plastic film 41 and a copper film laminated onto the plastic film 41. One exemplary embodiment of such a component is shown in FIG. 10. The copper film is processed by means of phototechnological and etching-technology process steps to form connection locations 4a, 4b. The configurations described in conjunction with FIGS. 1 to 8 are possible for such a component as well.

FIG. 11A shows a schematic plan view of a thirteenth exemplary embodiment of the surface-mounted component described here.

FIG. 11B shows a schematic sectional illustration along the line A-A′ of the surface-mounted component described in conjunction with FIG. 11A.

As can be gathered from the schematic plan view of FIG. 11A, the surface-mounted component in accordance with the thirteenth exemplary embodiment has a plurality of optoelectronic semiconductor chips 1. In this case, the optoelectronic semiconductor chips are arranged in matrixlike fashion. That is to say that the optoelectronic semiconductor chips 1 are arranged in rows and columns. In this case, it is possible for the optoelectronic semiconductor chips 1 to be semiconductor chips of identical type which essentially emit or detect electromagnetic radiation of the same wavelength range. Furthermore, it is possible for at least two of the optoelectronic semiconductor chips 1 to differ with regard to the wavelength range in which they emit or detect electromagnetic radiation.

By way of example, the surface-mounted component explained in conjunction with FIGS. 11A and 11B can form an area light source. The individual optoelectronic semiconductor chips 1 are then formed for example by luminescence diode chips. By introducing diffuser particles into the molded body or by forming the radiation exit area of the surface-mounted component in diffusely scattering fashion—for example by roughening the radiation exit area—it is possible to generate the impression that the radiation exit area of the optoelectronic component is a single, homogeneously luminous area. The individual optoelectronic semiconductor chips 1 can then no longer be perceived separately from one another. If the optoelectronic semiconductor chips 1 are for example luminescence diode chips suitable for emitting light of mutually different colors, then mixed light can be emitted by the surface-mounted component.

This patent application claims the priority of German patent application 102005041064.2-33, the disclosure content of which is hereby incorporated by reference.

The invention is not restricted by the description on the basis of the exemplary embodiments. Rather, the invention encompasses any new feature and also any combination of features, which in particular comprises any combination of features in the patent claims, even if this feature or this combination itself is not explicitly specified in the patent claims or exemplary embodiments.

1. A surface-mounted component, comprising:
an optoelectronic semiconductor chip;
a molded body integrally molded onto the semiconductor chips;
a mounting area formed at least in places by a surface of the molded body;
at least one connection location; and
side areas of the component which are produced by means of singulation.

2. The component as claimed in claim 1, in which the molded body is integrally molded onto the connection location.

3. The component as claimed in claim 1, in which the connection location is enclosed by the molded body at least in places.

4. The component as claimed in claim 1, in which the connection location has anchoring structures adapted for improving an adhesion of the molded body at the connection location.

5. The component as claimed in claim 1, in which the connection location has barbs for anchoring in the molded body.

6. The component as claimed in claim 1, in which the connection location is mushroom-shaped.

7. The component as claimed in claim 1, in which the connection location has etched structures.

8. The component as claimed in claim 1, in which the connection location has a mounting area onto which the optoelectronic semiconductor chip is fixed.

9. The component as claimed in claim 1, in which the connection location has a mounting area onto which an ESD protection element for the semiconductor chip is applied.

10. The component as claimed claim 9, in which a light emitting diode adapted for generating radiation is provided as ESD protection element.

11. The component as claimed in claim 1, in which the connection location has a connection area via which electrical contact can be made with the semiconductor chip from outside the optoelectronic component.

12. The component as claimed in claim 1, in which the connection area of a connection location terminates flush with the mounting area.

13. The component as claimed in claim 1, in which the connection area of a connection location projects beyond the mounting area.

14. The component as claimed in claim 1, in which the connection area of a connection location is arranged in a cutout of the mounting area.

15. The semiconductor component as claimed in claim 1,
in which the connection location is coated at least in places with a material adapted for improving the adhesion to the molded body.

16. The semiconductor component as claimed in claim 1,
in which the semiconductor chip is coated at least in places with a material adapted for improving the adhesion to the molded body.

17. The component as claimed in claim 1,
in which the ESD protection element (11) for the semiconductor chip is coated at least in places with a material adapted for improving the adhesion to the molded body.

18. The component as claimed in claim 1, in which a contact-making wire provided for making electrical contact with the semiconductor chip is coated with a material adapted for improving the adhesion to the molded body.

19. The component as claimed in claim 1, in which the material for improving the adhesion contains a silicate.

20. The component as claimed claim 19, in which the material has a thickness of at most 40 nm.

21. The component as claimed in claim 1, in which the molded body contains silicone.

22. The component as claimed in claim 1, in which the molded body contains epoxide.

23. The component as claimed in claim 1, in which the molded body contains an epoxide-silicone hybrid material.

24. The component as claimed in claim 1, in which the molded body contains at least one of the following materials: light-scattering particles, light-absorbing particles, glass fiber, mold release agent.

25. The component as claimed in claim 1, in which the molded body contains a luminescence conversion material.

26. The component as claimed claim 1, in which the molded body has an outer layer lying remote from the semiconductor chip and an inner layer enclosing the semiconductor chip, between which layers is situated a layer containing an additional material.

27. The component as claimed in claim 26, in which inner layer and outer layer are free of an additional material.

28. The component as claimed in claim 1, in which the molded body has a radiation passage area.

29. The component as claimed in claim 28,
in which the radiation passage area is formed in lenslike fashion.

30. The component as claimed in claim 1, in which the semiconductor chip is adapted for generating radiation.

31. The component as claimed in claim 1, in which the semiconductor chip is adapted for detecting radiation.

32. The component as claimed in claim 1, having a plurality of optoelectronic semiconductor chips.

33. The component as claimed in claim 32, in which the optoelectronic semiconductor chips are arranged in matrixlike fashion.

34. The component as claimed in claim 1, having a plurality of optoelectronic semiconductor chips, wherein at least two of the optoelectronic semiconductor chips differ with regard to the wavelength of the electromagnetic radiation emitted or detected by them during operation.

35. A method for the production of a surface-mounted optoelectronic component, comprising the steps of:
arranging a multiplicity of optoelectronic semiconductor chips in a cavity of a compression molding die or of a casting molding die;
encapsulating the semiconductor chips with a common molded body; and
severing the molded body for singulating the components.

36. The method as claimed in claim 35 wherein exclusively the molded body is severed for singulating the components.

37. The method as claimed in claim 35, wherein a connection location of the component is severed for singulating the components.

38. The method as claimed in claim 37, wherein the connection location is formed by a part of a leadframe.

39. The method as claimed in claim 37, wherein the connection location is formed by a part of a plastic film with electrically conductive coating.

40. The method as claimed in claim 35, wherein the molded body contains one of the following materials: epoxide, silicone, epoxide-silicone hybrid material.

41. The method as claimed in claim 40, wherein the materials are reaction-curing.

42. The method as claimed in claim 35, wherein prior to encapsulation with the molded body, component parts of the component are coated with a material adapted for increasing the adhesion to the molded body.

43. The method as claimed in claim 42, wherein the material comprises a silicate.

44. The method as claimed in claim 42, wherein the coating is effected by means of flame silicatization.
